(19) United States
(12) Patent Application Publication
(10) Pub. No.: US 2026/0025082 A1
(43) Pub. Date: Jan. 22, 2026

(54) POWER SEMICONDUCTOR DEVICE

(71) Applicant: Mitsubishi Electric Corporation, Tokyo (JP)

(72) Inventors: Kentaro YOSHIDA, Tokyo (JP); Hajime TAKAHASHI, Tokyo (JP)

(73) Assignee: Mitsubishi Electric Corporation, Tokyo (JP)

(21) Appl. No.: 19/189,159

(22) Filed: Apr. 24, 2025

(30) Foreign Application Priority Data
Jul. 16, 2024 (JP) 2024-113286

(51) Int. Cl. H02M 7/00; H01L 23/00; H01L 25/18; H02M 7/5387; H10D 80/20

(52) U.S. Cl. CPC H02M 7/003; H01L 25/18; H02M 7/5387; H10D 80/231; H01L 24/48; H01L 2224/48225; H01L 2924/10253; H01L 2924/10272; H01L 2924/13055; H01L 2924/13091; H10D 80/251

(57) ABSTRACT

A power semiconductor device includes a plurality of power modules. Outer shapes of packages of the plurality of power modules are the same. The plurality of power modules include a first half-bridge module made of a first semiconductor, and at least one of a second half-bridge module made of a second semiconductor, a second relay module made of a second semiconductor, and a second diode module made of a second semiconductor.

### BACKGROUND OF THE INVENTION

### Field of the Invention

The present disclosure relates to a power semiconductor device.

### Description of the Background Art

Various techniques have been proposed for power semiconductor devices. For example, Japanese Patent Application Laid-Open No. 2013-125806 proposes a power semiconductor device in which a semiconductor switching element made of silicon (Si) and a semiconductor switching element made of a wide band gap (WBG) semiconductor are connected in parallel in one power module. According to such a power semiconductor device, power loss and cost can be reduced.

However, in the configuration as in Japanese Patent Application Laid-Open No. 2013-125806, there is a problem that the imbalance of the current flowing through each semiconductor element becomes relatively large due to the difference in the material of each semiconductor element and the difference in the current path of each semiconductor element. Such an imbalance can be suppressed by adjusting the drive timing of each semiconductor element, but such adjustment causes another problem that the design becomes complicated.

### SUMMARY

The present disclosure has been made in view of the above problems, and an object of the present disclosure is to provide a technique capable of suppressing an imbalance of a current flowing through a semiconductor element.

A power semiconductor device according to the present disclosure including a plurality of power modules each including a semiconductor element, a package that covers the semiconductor element and has a rectangular shape in plan view, and a power terminal electrically connected to the semiconductor element, in which
outer shapes of the packages of the plurality of power modules are the same, the plurality of power modules include:
a first half-bridge module in which the semiconductor element is made of a first semiconductor that is one of Si and a wide bandgap semiconductor; and
at least one of a second half-bridge module in which the semiconductor element is made of a second semiconductor that is the other of the Si and the wide bandgap semiconductor and which is connected in parallel with the first half-bridge module, a second relay module made of the second semiconductor and electrically connected with the first half-bridge module, and a second diode module made of the second semiconductor and electrically connected with the first half-bridge module,
in each of the first half-bridge module and the second half-bridge module, the semiconductor element includes two semiconductor switching elements connected in series, and the power terminals are provided on both short sides of the package,
in the second relay module, the semiconductor element includes two semiconductor switching elements connected in anti-series, and the power terminal is provided on one or both short sides of the package, and
in the second diode module, the semiconductor element includes two diodes connected in series, and the power terminals are provided on both short sides of the package.

The imbalance of the current flowing through the semiconductor element can be suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a power semiconductor device according to a first preferred embodiment;

FIG. 2 is an equivalent circuit diagram illustrating a configuration of the power semiconductor device according to the first preferred embodiment;

FIG. 3 is a plan view and a side view illustrating an appearance of a half-bridge module according to the first preferred embodiment;

FIGS. 4A and 4B are equivalent circuit diagrams illustrating a configuration of the half-bridge module according to the first preferred embodiment;

FIG. 5 is a plan view illustrating a configuration of a power semiconductor device according to a second preferred embodiment;

FIG. 6 is an equivalent circuit diagram showing a configuration of the power semiconductor device according to the second preferred embodiment;

FIG. 7 is a plan view and a side view illustrating an appearance of a relay module according to the second preferred embodiment;

FIGS. 8A and 8B are equivalent circuit diagrams illustrating a configuration of the relay module according to the second preferred embodiment;

FIG. 9 is a plan view illustrating a configuration of a power semiconductor device according to a third preferred embodiment;

FIG. 10 is an equivalent circuit diagram showing a configuration of a power semiconductor device according to the third preferred embodiment;

FIG. 11 is a plan view and a side view illustrating an appearance of a relay module according to the third preferred embodiment;

FIGS. 12A and 12B are equivalent circuit diagrams illustrating a configuration of the relay module according to the third preferred embodiment;

FIG. 13 is a plan view illustrating a configuration of a power semiconductor device according to a fourth preferred embodiment;

FIG. 14 is an equivalent circuit diagram showing a configuration of the power semiconductor device according to the fourth preferred embodiment;

FIG. 15 is a plan view and a side view illustrating an appearance of a diode module according to the fourth preferred embodiment;

FIGS. 16A and 16B are equivalent circuit diagrams illustrating a configuration of the diode module according to the fourth preferred embodiment;

FIG. 17 is a plan view illustrating a configuration of a power semiconductor device according to a fifth preferred embodiment; and

FIG. 18 is an equivalent circuit diagram showing a configuration of the power semiconductor device according to the fifth preferred embodiment.

### DESCRIPTION OF THE PREFERRED EMBODIMENTS

Hereinafter, preferred embodiments will be described with reference to the accompanying drawings. Features described in the following preferred embodiments are examples, and all features are not necessarily essential. In the following description, similar components in a plurality of preferred embodiments are denoted by the same or similar reference numerals, and different components will be mainly described. Furthermore, in the following description, specific positions and directions such as “upper”, “lower”, “left”, “right”, “front”, or “back” may not necessarily coincide with actual positions and directions in practice.

### First Preferred Embodiment

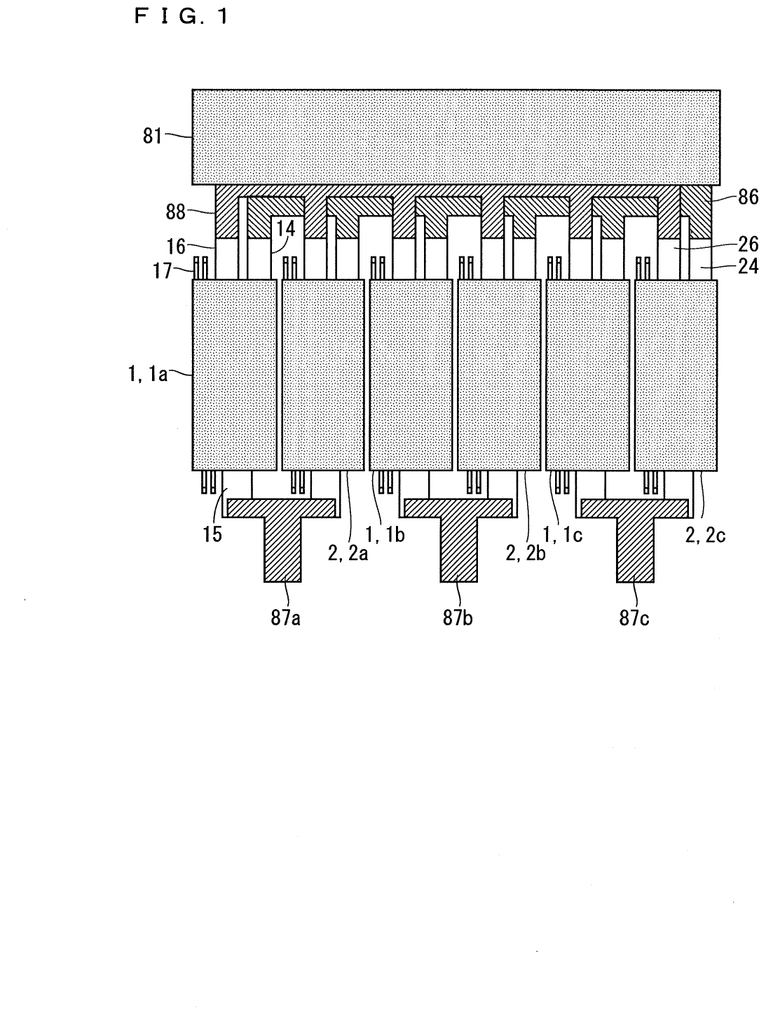

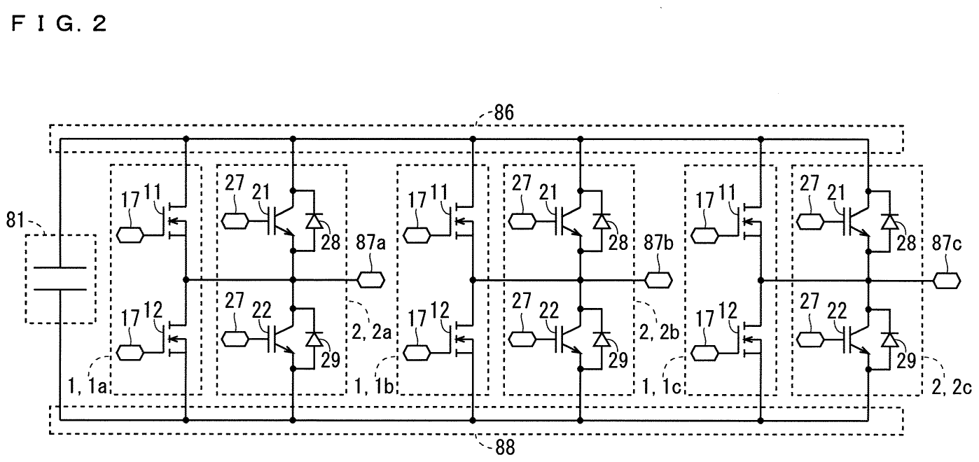

FIG. 1 is a plan view (top view) illustrating a configuration of a power semiconductor device according to a first preferred embodiment, and FIG. 2 is an equivalent circuit diagram of the configuration of FIG. 1. The power semiconductor device according to the first preferred embodiment includes a plurality of power modules. The plurality of power modules according to the first preferred embodiment include a first half-bridge module made of a first semiconductor and a second half-bridge module made of a second semiconductor.

Hereinafter, a case where the first semiconductor and the second semiconductor are silicon carbide (SIC) and silicon (Si), respectively, will be described. A case where SiC half-bridge modules 1a, 1b, and 1c in FIG. 1 are provided as a first half-bridge module, and Si half-bridge modules 2a, 2b, and 2c in FIG. 1 are provided as a second half-bridge module will be described. However, contrary to the above, the first semiconductor and the second semiconductor may be Si and SiC, respectively, or another wide bandgap semiconductor (for example, gallium nitride (GaN), gallium oxide (Ga₂O₃), diamond, and the like) may be used instead of SiC. The same applies to power modules other than the half-bridge module.

In the following description, the SiC half-bridge modules 1a, 1b, and 1c may be referred to as a SiC half-bridge module 1 without distinction, and the Si half-bridge modules 2a, 2b, and 2c may be referred to as a Si half-bridge module 2 without distinction. In the following description, the SiC half-bridge module 1 and the Si half-bridge module 2 may be referred to as half-bridge modules without distinction. In the following description, the number of each of the SiC half-bridge modules 1 and the Si half-bridge modules 2 is three, but the number is not limited thereto.

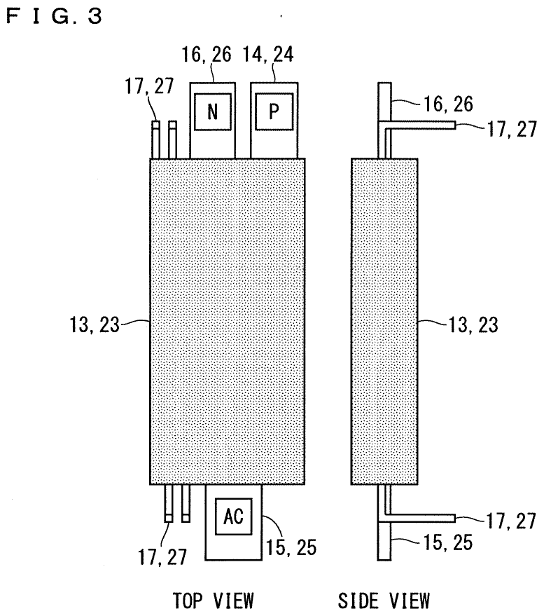

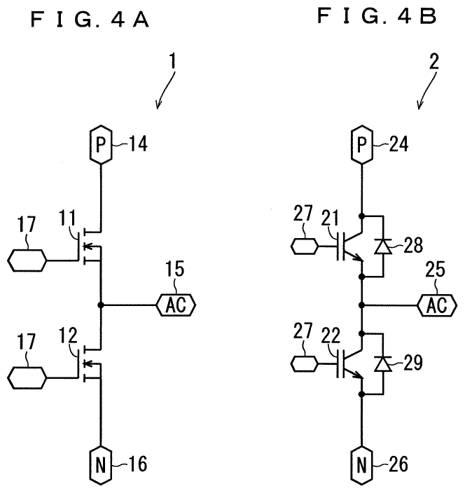

FIG. 3 is a plan view (top view) and a side view illustrating the appearance of the half-bridge module, and FIGS. 4A and 4B are equivalent circuit diagrams of the SiC half-bridge module 1 and the Si half-bridge module 2, respectively. Hereinafter, configurations of the SiC half-bridge module 1 and the Si half-bridge module 2 will be described.

### <SiC Half-Bridge Module 1>

As illustrated in FIGS. 3 and 4A, the SiC half-bridge module 1 includes metal oxide semiconductor field effect transistors (MOSFETs) 11 and 12 which are semiconductor elements, a package 13, power terminals 14, 15, and 16, and a control terminal 17. The two sets of control terminals 17 in FIG. 3 correspond to the two control terminals 17 in FIG. 4A, and the same applies to the other control terminals.

The MOSFETs 11 and 12 are two semiconductor switching elements connected in series. In the first preferred embodiment, the two semiconductor switching elements of the SiC half-bridge module 1 are Nch MOSFETs, but may be, for example, Pch MOSFETs, insulated gate bipolar transistors (IGBTs), high electron mobility transistors (HEMTs), or reverse conducting-IGBTs (RC-IGBTs).

The package 13 of FIG. 3 is a resin package that covers the MOSFETs 11 and 12 and has a rectangular shape in plan view. The power terminals 14 and 16 are DC input terminals (P terminal and N terminal) provided on one short side of the package 13, and the power terminal 15 is an A C output terminal provided on the other short side of the package 13. In FIG. 3, one of the two sets of control terminals 17 is provided on one short side of the package 13, and the other of the two sets of control terminals 17 is provided on the other short side of the package 13. However, the positions and pin assignments of the two sets of control terminals 17 are not limited to those in FIG. 3.

As illustrated in FIG. 4A, the power terminal 14, which is a P terminal, is electrically connected to the drain of the MOSFET 11. The source of the MOSFET 11 and the drain of the MOSFET 12 are electrically connected, and the MOSFETs 11 and 12 are connected in series. The power terminal 15, which is an A C output terminal, is electrically connected to the source of the MOSFET 11 and the drain of the MOSFET 12. The power terminal 16, which is an N terminal, is electrically connected to the source of the MOSFET 12. The two control terminals 17 are electrically connected to the gates of the MOSFETS 11 and 12, respectively.

### <Si Half-Bridge Module 2>

As illustrated in FIGS. 3 and 4B, the Si half-bridge module 2 includes IGBTs 21 and 22, which are semiconductor elements, a package 23, power terminals 24, 25, and 26, a control terminal 27, and diodes 28 and 29.

The IGBTs 21 and 22 are two semiconductor switching elements connected in series. In the first preferred embodiment, the two semiconductor switching elements of the Si half-bridge module 2 are IGBTs, but may be, for example, MOSFETs, HEMTs, or RC-IGBTs.

The package 23 in FIG. 3 is a resin package that covers the IGBTs 21 and 22 and has a rectangular shape in plan view. Note that the outer shapes of the package 13 of the SiC half-bridge modules 1a, 1b, and 1c and the package 23 of the Si half-bridge modules 2a, 2b, and 2c are the same. The fact that the outer shapes of the packages are the same includes that the outer shapes of the packages are different by, for example, 5% or less.

The power terminals 24 and 26 are DC input terminals (P terminal and N terminal) provided on one short side of the package 23, and the power terminal 25 is an A C output terminal provided on the other short side of the package 23. In FIG. 3, one of the two sets of control terminals 27 is provided on one short side of the package 23, and the other of the two sets of control terminals 27 is provided on the other short side of the package 23. However, the positions and pin assignments of the two sets of control terminals 27 are not limited to those in FIG. 3.

As shown in FIG. 4B, the power terminal 24, which is a P terminal, is electrically connected to the collector of the IGBT 21. The emitter of the IGBT 21 and the collector of the IGBT 22 are electrically connected, and the IGBTs 21 and 22 are connected in series. The power terminal 25, which is an AC output terminal, is electrically connected to the emitter of the IGBT 21 and the collector of the IGBT 22. The power terminal 26, which is an N terminal, is electrically connected to the emitter of the IGBT 22. The two control terminals 27 are electrically connected to the gates of the IGBTs 21 and 22, respectively. The diode 28 is connected in anti-parallel with the IGBT 21, and the diode 29 is connected in anti-parallel with the IGBT 22.

### Overall Configuration

The power semiconductor device illustrated in FIGS. 1 and 2 includes not only a half-bridge module but also a DC link capacitor 81, a P bus bar 86, AC bus bars 87a, 87b, and 87c, and an N bus bar 88.

The power terminal 14 which is a P terminal of the SiC half-bridge modules 1a, 1b, and 1c, a power terminal 24 which is a P terminal of the Si half-bridge modules 2a, 2b, and 2c, and one end of the DC link capacitor 81 are electrically connected by the P bus bar 86.

The power terminal 16 which is an N terminal of the SiC half-bridge modules 1a, 1b, and 1c, the power terminal 26 which is an N terminal of the Si half-bridge modules 2a, 2b, and 2c, and the other end of the DC link capacitor 81 are electrically connected by the N bus bar 88.

The power terminals 15 which are AC output terminals of the SiC half-bridge modules 1a, 1b, and 1c and the power terminals 25 which are AC output terminals of the Si half-bridge modules 2a, 2b, and 2c are electrically connected by the AC bus bars 87a, 87b, and 87c, respectively.

As described above, in the first preferred embodiment, the SiC half-bridge modules 1a, 1b, and 1c, the Si half-bridge modules 2a, 2b, and 2c, and the DC link capacitor 81 are connected in parallel. As a result, a three-phase inverter is realized.

### Summary of First Preferred Embodiment

The SiC half-bridge module 1 can reduce power loss in a small current range, but increases power loss in a large current range and is expensive. On the other hand, the Si half-bridge module 2 can reduce the power loss in a large current region and is inexpensive, but the power loss increases in a small current region. On the other hand, since the power semiconductor device according to the first preferred embodiment includes the SiC half-bridge module 1 and the Si half-bridge module 2, the power loss and the cost can be appropriately reduced.

In the first preferred embodiment, the outer shapes of the package 13 of the SiC half-bridge module 1 and the package 23 of the Si half-bridge module 2 are the same. Therefore, since the inductances of the current path of the SiC half-bridge module 1 and the current path of the Si half-bridge module 2 can be made substantially equal to each other, it is possible to suppress the imbalance of the currents flowing through the semiconductor elements of the half-bridge modules connected in parallel.

Further, since the power terminals 14 to 16 and 24 to 26 are provided on the short sides of the packages 13 and 23, the bus bar connecting the half-bridge modules can be shortened. Accordingly, reduction in inductance between half-bridge modules and downsizing of the power semiconductor device can be expected.

In addition, since one function of a half bridge is realized by one package (one power module), optimal control can be performed for each power module. In addition, since the power modules are easily connected, for example, the number of power modules to be connected can be easily changed according to the power capacity.

### Second Preferred Embodiment

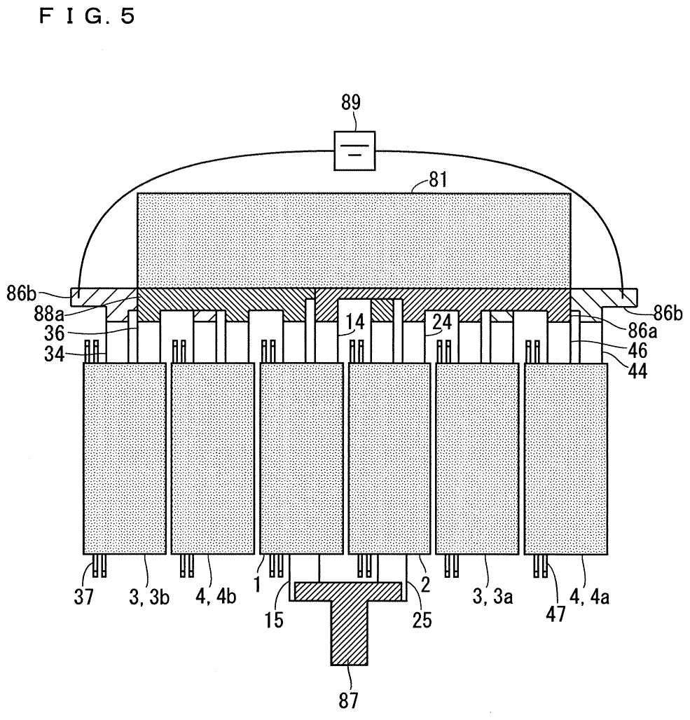

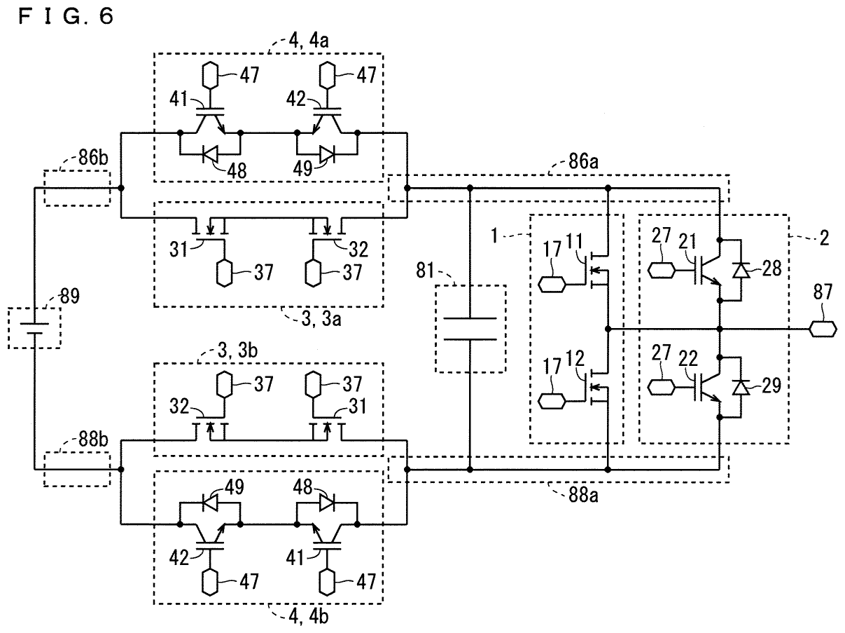

FIG. 5 is a plan view (top view) illustrating a configuration of a power semiconductor device according to a second preferred embodiment, and FIG. 6 is an equivalent circuit diagram of the configuration of FIG. 5. The power semiconductor device according to the second preferred embodiment includes a plurality of power modules. The plurality of power modules according to the second preferred embodiment include a SiC half-bridge module 1, a Si half-bridge module 2, a SiC relay module 3 (3a, 3b) made of SiC, and a Si relay module 4 (4a, 4b) made of Si. In the following description, the SiC relay module 3 and the Si relay module 4 may be referred to as relay modules without distinction.

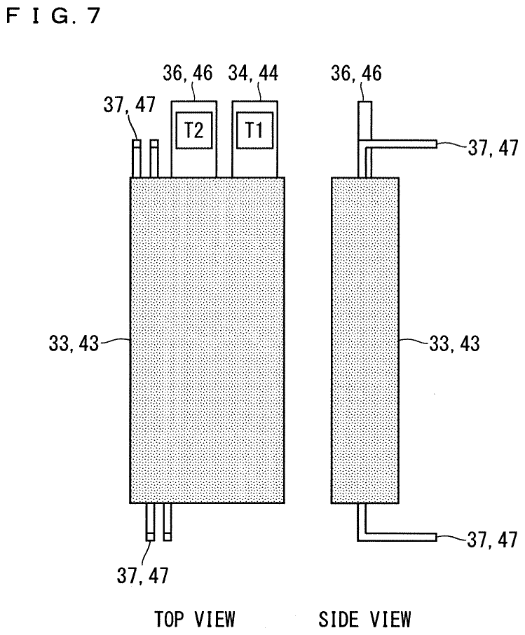

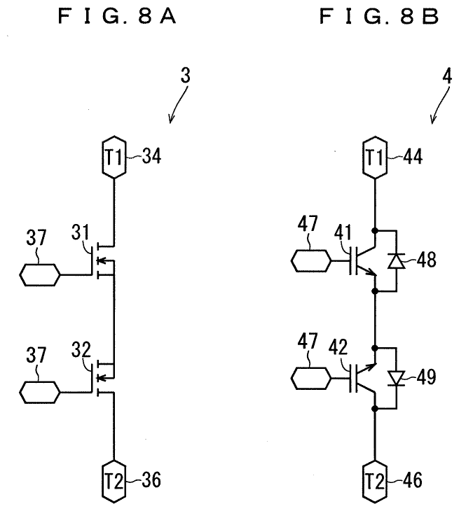

FIG. 7 is a plan view (top view) and a side view illustrating the appearance of the relay module, and FIGS. 8A and 8B are equivalent circuit diagrams of the SiC relay module 3 and the Si relay module 4, respectively. Hereinafter, configurations of the SiC relay module 3 and the Si relay module 4 will be described.

### <SiC Relay Module 3>

As illustrated in FIGS. 7 and 8A, the bidirectional SiC relay module 3 includes MOSFETs 31 and 32 which are semiconductor elements, a package 33, power terminals 34 and 36, and a control terminal 37.

The MOSFETs 31 and 32 are two semiconductor switching elements connected in anti-series. In the second preferred embodiment, the two semiconductor switching elements of the SiC relay module 3 are Nch MOSFETs, but may be Pch MOSFETs, IGBTs, HEMTs, or RC-IGBTs, for example.

The package 33 of FIG. 7 is a resin package that covers the MOSFETs 31 and 32 and has a rectangular shape in plan view. The power terminals 34 and 36 are a T1 terminal and a T2 terminal provided on one short side of the package 33. In FIG. 7, one of the two sets of control terminals 37 is provided on one short side of the package 33, and the other of the two sets of control terminals 37 is provided on the other short side of the package 33, but the positions and pin assignments of the two sets of control terminals 37 are not limited to those in FIG. 7.

As illustrated in FIG. 8A, the power terminal 34 which is the T1 terminal is electrically connected to the drain of the MOSFET 31. The sources of the MOSFETs 31 and 32 are electrically connected to each other, and the MOSFETs 31 and 32 are connected in anti-series. The power terminal 36, which is the T2 terminal, is electrically connected to the drain of the MOSFET 32. The two control terminals 37 are electrically connected to the gates of the MOSFETs 31 and 32, respectively. In FIG. 8A, the sources of the MOSFETs 31 and 32 are electrically connected to each other, but the drains of the MOSFETs 31 and 32 may be electrically connected to each other instead of the sources.

### <Si Relay Module 4>

As illustrated in FIGS. 7 and 8B, the bidirectional Si relay module 4 includes IGBTs 41 and 42 which are semiconductor elements, a package 43, power terminals 44 and 46, a control terminal 47, and diodes 48 and 49.

The IGBTs 41 and 42 are two semiconductor switching elements connected in anti-series. In the second preferred embodiment, the two semiconductor switching elements of the Si relay module 4 are IGBTs, but may be, for example, MOSFETs, HEMTs, or RC-IGBTs.

The package 43 in FIG. 7 is a resin package that covers the IGBTs 41 and 42 and has a rectangular shape in plan view. Note that the outer shapes of the package 13 of the SiC half-bridge module 1, the package 23 of the Si half-bridge module 2, the package 33 of the SiC relay modules 3a and 3b, and the package 43 of the Si relay modules 4a and 4b are the same.

The power terminals 44 and 46 are a T1 terminal and a T2 terminal provided on one short side of the package 43. In FIG. 7, one of the two sets of control terminals 47 is provided on one short side of the package 43, and the other of the two sets of control terminals 47 is provided on the other short side of the package 43, but the positions and pin assignments of the two sets of control terminals 47 are not limited to those in FIG. 7.

As illustrated in FIG. 8B, the power terminal 44 which is the T1 terminal is electrically connected to the collector of the IGBT 41. The emitters of the IGBTs 41 and 42 are electrically connected to each other, and the IGBTs 41 and 42 are connected in anti-series. The power terminal 46, which is the T2 terminal, is electrically connected to the collector of the IGBT 42. The two control terminals 47 are electrically connected to the gates of the IGBTs 41 and 42, respectively. The diode 48 is connected in anti-parallel with the IGBT 41, and the diode 49 is connected in anti-parallel with the IGBT 42. In FIG. 8B, the emitters of the IGBTs 41 and 42 are electrically connected to each other, but the collectors of the IGBTs 41 and 42 may be electrically connected to each other instead of the emitters.

### Overall Configuration

The power semiconductor device illustrated in FIGS. 5 and 6 includes not only a half-bridge module and a relay module but also a DC link capacitor 81, P bus bars 86a and 86b, an AC bus bar 87, N bus bars 88a and 88b, and a DC power supply 89 as a power supply.

The power terminal 14 of the SiC half-bridge module 1, the power terminal 24 of the Si half-bridge module 2, the power terminal 36 of the SiC relay module 3a, the power terminal 46 of the Si relay module 4a, and one end of the DC link capacitor 81 are electrically connected by the P bus bar 86a. The power terminal 34 of the SiC relay module 3a, the power terminal 44 of the Si relay module 4a, and the positive pole of the DC power supply 89 are electrically connected by the P bus bar 86b. As a result, connection and disconnection between the P bus and the DC power supply 89 can be switched by the SiC relay module 3a and the Si relay module 4a.

The power terminal 16 of the SiC half-bridge module 1, the power terminal 26 of the Si half-bridge module 2, the power terminal 34 of the SiC relay module 3b, the power terminal 44 of the Si relay module 4b, and the other end of the DC link capacitor 81 are electrically connected by the N bus bar 88a. The power terminal 36 of the SiC relay module 3b, the power terminal 46 of the Si relay module 4b, and the negative pole of the DC power supply 89 are electrically connected by the N bus bar 88b. As a result, connection and disconnection between the N bus and the DC power supply 89 can be switched by the SiC relay module 3b and the Si relay module 4b.

The power terminal 15 of the SiC half-bridge module 1 and the power terminal 25 of the Si half-bridge module 2 are electrically connected by the A C bus bar 87.

As described above, in the second preferred embodiment, the SiC relay modules 3a and 3b and the Si relay modules 4a and 4b are electrically and selectively connected between the PN buses of the SiC half-bridge module 1 and the Si half-bridge module 2 and the DC power supply 89. As a result, an inverter having a function of switching connection/disconnection with the DC power supply 89 is realized.

### Summary of Second Preferred Embodiment

Since the power semiconductor device according to the second preferred embodiment includes the Si relay module 4 for the SiC half-bridge module 1 and includes the SiC relay module 3 for the Si half-bridge module 2, it is possible to appropriately reduce power loss and cost.

In the second preferred embodiment, the outer shapes of the package 13 of the SiC half-bridge module 1, the package 23 of the Si half-bridge module 2, the package 33 of the SiC relay modules 3a and 3b, and the package 43 of the Si relay modules 4a and 4b are the same. For this reason, since the inductance of the current path of the power module made of SiC and the inductance of the current path of the power module made of Si can be made substantially equal, it is possible to suppress the imbalance of the current flowing through the semiconductor element of each power module.

In the second preferred embodiment, the power terminal is provided on the short side of the package, so that the bus bar connecting the power modules can be shortened. Accordingly, reduction in inductance between the power modules and downsizing of the power semiconductor device can be expected.

### Modification

When the first half-bridge module is the SiC half-bridge module 1, the second half-bridge module is the Si half-bridge module 2, the second relay module is the Si relay module 4, and the third relay module is the SiC relay module 3. On the other hand, when the first half-bridge module is the Si half-bridge module 2, the second half-bridge module is the SiC half-bridge module 1, the second relay module is the SiC relay module 3, and the third relay module is the Si relay module 4.

The plurality of power modules according to the second preferred embodiment may be configured to include one or more first half-bridge modules and one or more second relay modules. At least one of one or more second half-bridge modules and one or more third relay modules may be appropriately added to this configuration. In the present specification, for example, at least one of A, B, C, . . . , and Z means any one of all combinations extracted from one or more groups of A, B, C, . . . , and Z.

### Third Preferred Embodiment

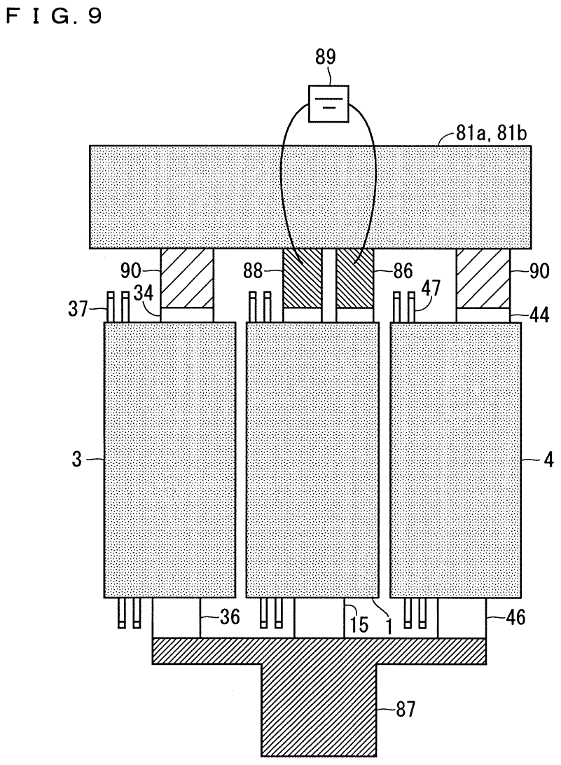

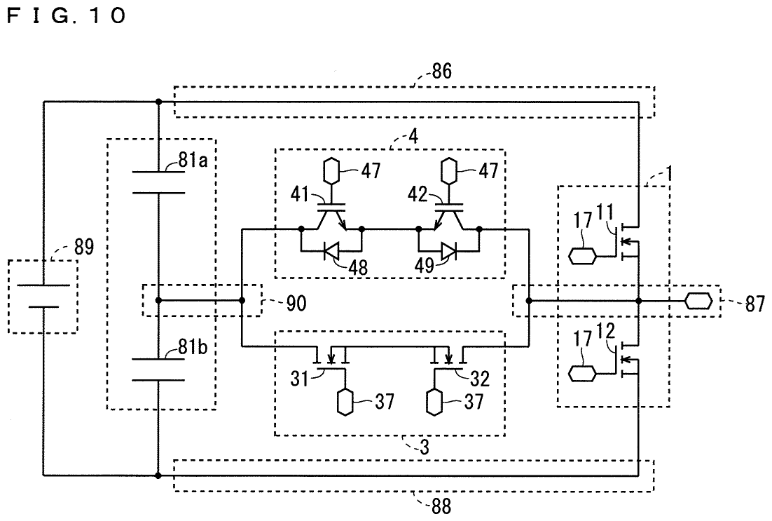

FIG. 9 is a plan view (top view) illustrating a configuration of a power semiconductor device according to a third preferred embodiment, and FIG. 10 is an equivalent circuit diagram of the configuration of FIG. 9. The power semiconductor device according to the third preferred embodiment includes a plurality of power modules. The plurality of power modules according to the third preferred embodiment include a SiC half-bridge module 1, a SiC relay module 3, and a Si relay module 4.

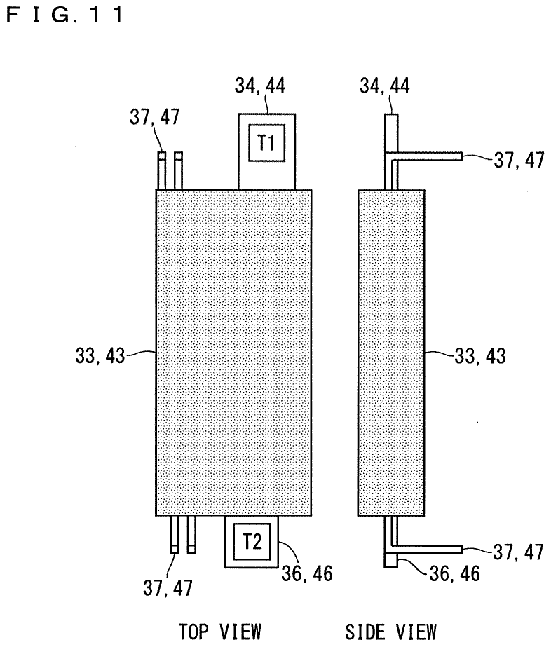

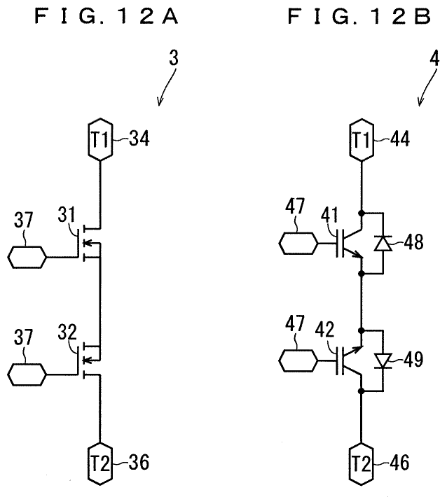

FIG. 11 is a plan view (top view) and a side view illustrating the appearance of the relay module, and FIGS. 12A and 12B are equivalent circuit diagrams of the SiC relay module 3 and the Si relay module 4, respectively. The SiC relay module 3 according to the third preferred embodiment is similar to the SiC relay module 3 according to the second preferred embodiment except that the power terminals 34 and 36 are a T1 terminal and a T2 terminal respectively provided on two short sides of the package 33. The Si relay module 4 according to the third preferred embodiment is similar to the Si relay module 4 according to the second preferred embodiment except that the power terminals 44 and 46 are a T1 terminal and a T2 terminal respectively provided on two short sides of the package 43.

### Overall Configuration

The power semiconductor device illustrated in FIGS. 9 and 10 includes not only a half-bridge module and a relay module but also DC link capacitors 81a and 81b, a P bus bar 86, an AC bus bar 87, an N bus bar 88, a DC power supply 89, and a U bus bar 90.

The power terminal 14 of the SiC half-bridge module 1, one end of the DC link capacitor 81a, and the positive pole of the DC power supply 89 are electrically connected by the P bus bar 86. The power terminal 16 of the SiC half-bridge module 1, one end of the DC link capacitor 81b, and the negative pole of the DC power supply 89 are electrically connected by the N bus bar 88.

The power terminal 15 of the SiC half-bridge module 1, the power terminal 36 of the SiC relay module 3, and the power terminal 46 of the Si relay module 4 are electrically connected by the A C bus bar 87. A connection point between the other ends of the DC link capacitors 81a and 81b having an intermediate potential of the DC power supply 89, the power terminal 34 of the SiC relay module 3, and the power terminal 44 of the Si relay module 4 are electrically connected by the U bus bar 90.

As described above, in the third preferred embodiment, the SiC relay module 3 and the Si relay module 4 are electrically connected between the power terminal 15 which is the output terminal of the SiC half-bridge module 1 and the intermediate potential of the DC power supply 89. As a result, a three-level inverter is realized.

### Summary of Third Preferred Embodiment

Since the power semiconductor device according to the third preferred embodiment includes the Si relay module 4 for the SiC half-bridge module 1, the power loss and the cost can be appropriately reduced. In addition, similarly to the second preferred embodiment, it is possible to suppress the imbalance of the current flowing through the semiconductor element of each power module, and it is expected to realize the reduction in the inductance between the power modules and the miniaturization of the power semiconductor device.

### Modification

The plurality of power modules according to the third preferred embodiment may be configured to include one or more first half-bridge modules and one or more second relay modules. At least one of one or more second half-bridge modules and one or more third relay modules may be appropriately added to this configuration.

### Fourth Preferred Embodiment

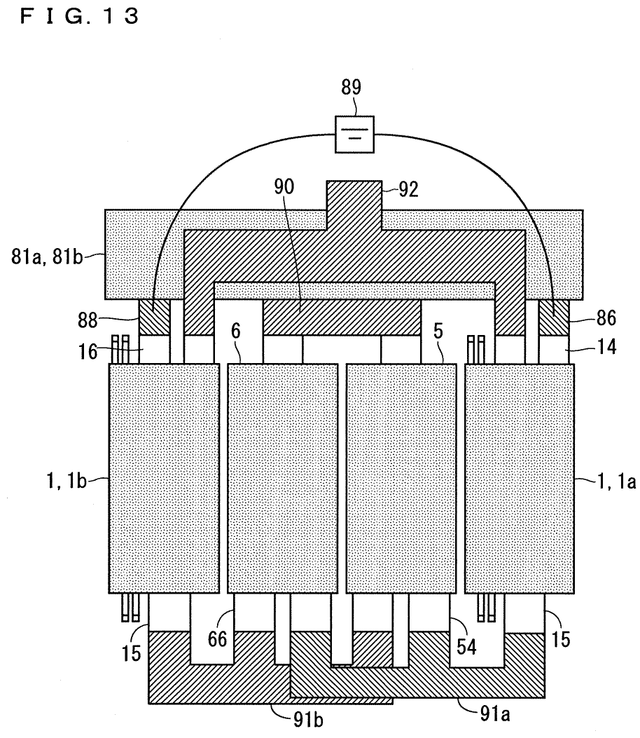

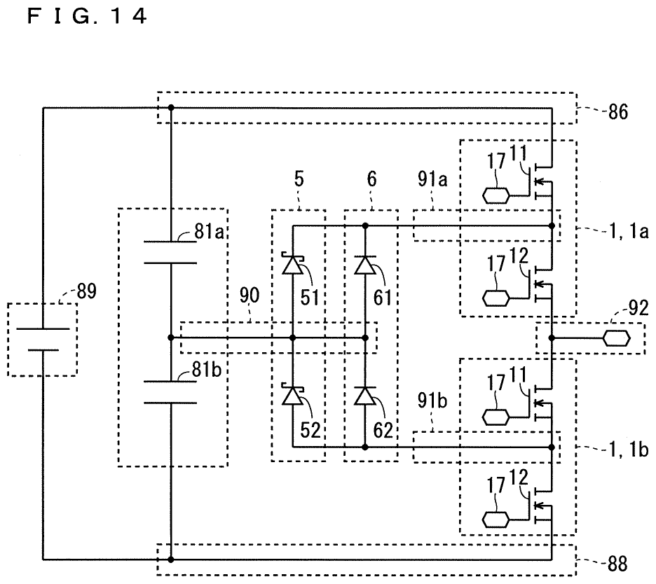

FIG. 13 is a plan view (top view) illustrating a configuration of a power semiconductor device according to a fourth preferred embodiment, and FIG. 14 is an equivalent circuit diagram of the configuration of FIG. 13. The power semiconductor device according to the fourth preferred embodiment includes a plurality of power modules. The plurality of power modules according to the fourth preferred embodiment include a SiC half-bridge module 1 (1a, 1b), a SiC diode module 5 made of SiC, and a Si diode module 6 made of Si. In the following description, the SiC diode module 5 and the Si diode module 6 may be referred to as diode modules without distinction.

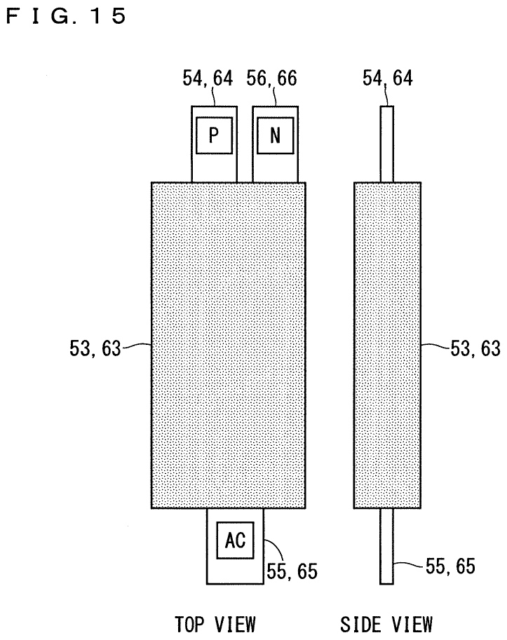

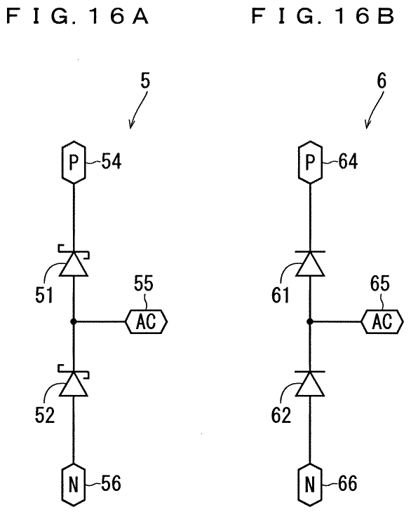

FIG. 15 is a plan view (top view) and a side view illustrating the appearance of the diode module, and FIGS. 16A and 16B are equivalent circuit diagrams of the SiC diode module 5 and the Si diode module 6, respectively. Hereinafter, configurations of the SiC diode module 5 and the Si diode module 6 will be described.

### <SiC Diode Module 5>

As illustrated in FIGS. 15 and 16A, the SiC diode module 5 includes SiC diodes 51 and 52 which are semiconductor elements, a package 53, and power terminals 54, 55, and 56.

The SiC diodes 51 and 52 are two diodes connected in series. The package 53 of FIG. 15 is a resin package that covers the SiC diodes 51 and 52 and has a rectangular shape in plan view. The power terminals 54 and 56 are a P terminal and an N terminal provided on one short side of the package 53, and the power terminal 55 is an A C terminal provided on the other short side of the package 53.

As illustrated in FIG. 16A, the power terminal 54 which is a P terminal is electrically connected to the cathode of the SiC diode 51. The anode of the SiC diode 51 and the cathode of the SiC diode 52 are electrically connected, and the SiC diodes 51 and 52 are connected in series. The power terminal 55, which is an AC terminal, is electrically connected to the anode of the SiC diode 51 and the cathode of the SiC diode 52. The power terminal 56, which is an N terminal, is electrically connected to the anode of the SiC diode 52.

### <Si Diode Module 6>

As illustrated in FIGS. 15 and 16B, the Si diode module 6 includes Si diodes 61 and 62 which are semiconductor elements, a package 63, and power terminals 64, 65, and 66.

The Si diodes 61 and 62 are diodes connected in series. The package 63 of FIG. 15 is a resin package that covers the Si diodes 61 and 62 and has a rectangular shape in plan view. Note that the outer shapes of the package 13 of the SiC half-bridge modules 1a and 1b, the package 53 of the SiC diode module 5, and the package 63 of the Si diode module 6 are the same. The power terminals 64 and 66 are a P terminal and an N terminal provided on one short side of the package 63, and the power terminal 65 is an AC terminal provided on the other short side of the package 63.

As illustrated in FIG. 16B, the power terminal 64 which is a P terminal is electrically connected to the cathode of the Si diode 61. The anode of the Si diode 61 and the cathode of the Si diode 62 are electrically connected, and the Si diodes 61 and 62 are connected in series. The power terminal 65, which is an AC terminal, is electrically connected to the anode of the Si diode 61 and the cathode of the Si diode 62. The power terminal 66, which is an N terminal, is electrically connected to the anode of the Si diode 62.

### Overall Configuration

The power semiconductor device illustrated in FIGS. 13 and 14 includes not only a half-bridge module and a diode module but also DC link capacitors 81a and 81b, a P bus bar 86, an N bus bar 88, a DC power supply 89, a U bus bar 90, bus bars 91a and 91b, and an output bus bar 92.

The power terminal 14 of the SiC half-bridge module 1a, one end of the DC link capacitor 81a, and the positive pole of the DC power supply 89 are electrically connected by the P bus bar 86. The power terminal 16 of the SiC half-bridge module 1b, one end of the DC link capacitor 81b, and the negative pole of the DC power supply 89 are electrically connected by the N bus bar 88. The power terminal 16 of the SiC half-bridge module 1a and the power terminal 14 of the SiC half-bridge module 1b are electrically connected by the output bus bar 92.

The power terminal 54 of the SiC diode module 5, the power terminal 64 of the Si diode module 6, and the power terminal 15 of the SiC half-bridge module 1a are electrically connected by the bus bar 91a. The power terminal 56 of the SiC diode module 5, the power terminal 66 of the Si diode module 6, and the power terminal 15 of the SiC half-bridge module 1b are electrically connected by the bus bar 91b. A connection point between the other ends of the DC link capacitors 81a and 81b having an intermediate potential of the DC power supply 89, the power terminal 55 of the SiC diode module 5, and the power terminal 65 of the Si diode module 6 are electrically connected by the U bus bar 90.

As described above, in the fourth preferred embodiment, the SiC diode module 5 and the Si diode module 6 are electrically and selectively connected between the connection point between the MOSFETs 11 and 12 and the IGBTs 21 and 22 included in the SiC half-bridge modules 1a and 1b and the intermediate potential of the DC power supply 89. As a result, an NPC-type three-level inverter is realized.

### Summary of Fourth Preferred Embodiment

Since the power semiconductor device according to the fourth preferred embodiment includes the Si diode module 6 for the SiC half-bridge module 1, the power loss and the cost can be appropriately reduced. In addition, similarly to the second preferred embodiment, it is possible to suppress the imbalance of the current flowing through the semiconductor element of each power module, and it is expected to realize the reduction in the inductance between the power modules and the miniaturization of the power semiconductor device.

### Modification

In the fourth preferred embodiment, the first half-bridge module is the SiC half-bridge module 1, the second diode module is the Si diode module 6, and the third diode module is the SiC diode module 5, but the present invention is not limited thereto.

The plurality of power modules according to the fourth preferred embodiment may be configured to include one or more first half-bridge modules and one or more second diode modules. At least one of one or more second half-bridge modules and one or more third diode modules may be appropriately added to this configuration.

Further, by combining the first to fourth preferred embodiments, the plurality of power modules may include at least one of one or more second half-bridge modules, one or more second relay modules, and one or more second diode modules, and one or more first half-bridge modules. At least one of one or more third relay modules and one or more third diode modules may be appropriately added to this configuration.

### Fifth Preferred Embodiment

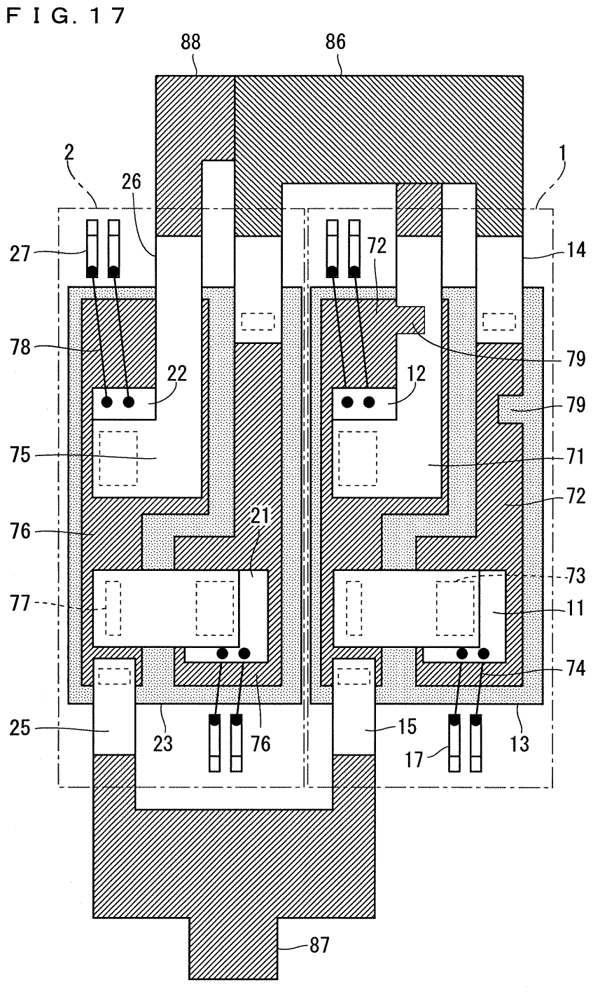

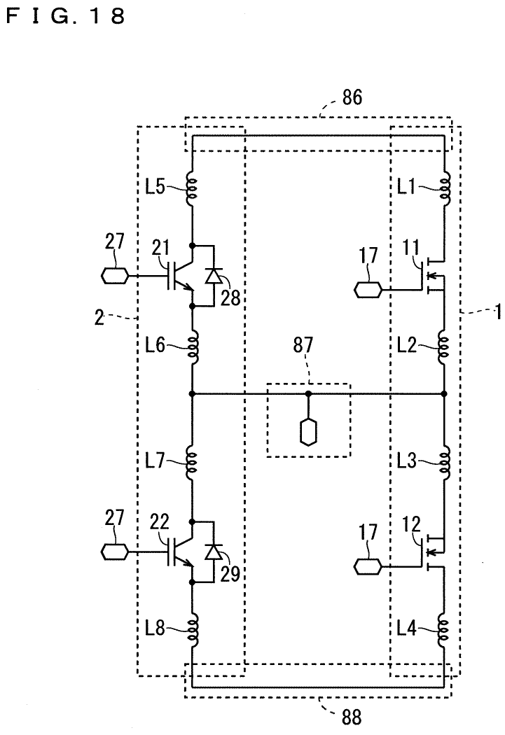

FIG. 17 is a plan view (top view) illustrating a configuration of a power semiconductor device according to the present preferred embodiment 5, and FIG. 18 is an equivalent circuit diagram of the configuration of FIG. 17. In FIG. 18, illustration of the front side portions of the packages 13 and 23 of the SiC half-bridge module 1 and the Si half-bridge module 2 is omitted.

In the SiC half-bridge module 1, a frame 71 partially used as a power terminal is selectively connected to the MOSFETs 11 and 12 and a metal pattern 72 via a bonding region 73. Wires 74 are connected between the MOSFETs 11 and 12 and the two sets of control terminals 17.

In the Si half-bridge module 2, a frame 75 partially used as a power terminal, is selectively connected to the IGBTs 21 and 22 and a metal pattern 76 via a bonding region 77. Wires 78 are connected between the IGBTs 21 and 22 and the two sets of control terminals 27.

Notches 79 are selectively provided in path portions of the main current in the plurality of power modules. In the example of FIG. 17, the notches 79 are provided in the frame 71 and the metal pattern 72 which are path portions of the main current in the SiC half-bridge module 1.

### Summary of Fifth Preferred Embodiment

In the first to fourth preferred embodiments, the imbalance of the current is suppressed by making the inductances of the current paths substantially equal, that is, L1=L5, L2=L6, L3=L7, and L4=L8 in FIG. 18. However, depending on the difference in characteristics of the elements, the imbalance of the current may not be sufficiently suppressed only by making the inductances of the current paths substantially equal.

On the other hand, according to the power semiconductor device of the fifth preferred embodiment, the inductance of the path portion of the main current can be adjusted by the notch 79. Therefore, it is possible to suppress the imbalance of the current when power modules including different elements are driven in parallel.

For example, it is assumed that the switching speed of the SiC half-bridge module 1 is high and switching is performed earlier than that of the Si half-bridge module 2. In such a case, the notch may be provided in the path portion of the main current of the SiC half-bridge module 1 without providing the notch in the path portion of the main current of the Si half-bridge module 2. According to such a configuration, since the inductance of the SiC half-bridge module 1 can be increased, the imbalance of the current flowing through the semiconductor element can be suppressed.

In the present disclosure in English, ‘a’ and ‘an’ mean one or more. Thus, ‘a’, ‘an’, ‘one or more’ and ‘at least one’ can be used interchangeably.

Note that the preferred embodiments and the modifications can be freely combined, and the preferred embodiments and the modifications can be appropriately modified or omitted.

Hereinafter, various aspects of the present disclosure will be collectively described as Appendices.

### Appendix 1

A power semiconductor device comprising a plurality of power modules each including a semiconductor element, a package that covers the semiconductor element and has a rectangular shape in plan view, and a power terminal electrically connected to the semiconductor element, wherein
outer shapes of the packages of the plurality of power modules are the same,
the plurality of power modules include:
a first half-bridge module in which the semiconductor element is made of a first semiconductor that is one of Si and a wide bandgap semiconductor; and
at least one of a second half-bridge module in which the semiconductor element is made of a second semiconductor that is the other of the Si and the wide bandgap semiconductor and which is connected in parallel with the first half-bridge module, a second relay module made of the second semiconductor and electrically connected with the first half-bridge module, and a second diode module made of the second semiconductor and electrically connected with the first half-bridge module,
in each of the first half-bridge module and the second half-bridge module, the semiconductor element includes two semiconductor switching elements connected in series, and the power terminals are provided on both short sides of the package,
in the second relay module, the semiconductor element includes two semiconductor switching elements connected in anti-series, and the power terminal is provided on one or both short sides of the package, and
in the second diode module, the semiconductor element includes two diodes connected in series, and the power terminals are provided on both short sides of the package.

### Appendix 2

The power semiconductor device according to Appendix 1, wherein
the plurality of power modules include the second half-bridge module.

### Appendix 3

The power semiconductor device according to Appendix 1, wherein
the plurality of power modules include the second relay module.

### Appendix 4

The power semiconductor device according to Appendix 3, wherein
the second relay module is electrically connected between a P bus or an N bus of the first half-bridge module and a power supply.

### Appendix 5

The power semiconductor device according to Appendix 3 or 4, wherein
the second relay module is electrically connected between an output terminal of the first half-bridge module and an intermediate potential of a power supply.

### Appendix 6

The power semiconductor device according to any one of Appendices 3 to 5, wherein
the plurality of power modules further include a third relay module made of the first semiconductor and connected in parallel with the second relay module, and
in the third relay module, the semiconductor element includes two semiconductor switching elements connected in anti-series, and the power terminal is provided on one or both short sides of the package.

### Appendix 7

The power semiconductor device according to Appendix 1, wherein
the plurality of power modules include the second diode module.

### Appendix 8

The power semiconductor device according to Appendix 7, wherein
the second diode module is electrically connected between a connection point between the two semiconductor switching elements included in the first half-bridge module and an intermediate potential of a power supply, thereby implementing an NPC-type 3-level inverter.

### Appendix 9

The power semiconductor device according to Appendix 7 or 8, wherein
the plurality of power modules further include a third diode module made of the first semiconductor and connected in parallel with the second diode module, and
in the third diode module, the semiconductor element includes two diodes connected in series, and the power terminals are provided on both short sides of the package.

### Appendix 10

The power semiconductor device according to any one of Appendices 1 to 9, wherein
a notch is selectively provided in a path portion of a main current in the plurality of power modules.

While the disclosure has been shown and described in detail, the foregoing description is in all aspects illustrative and not restrictive. It is therefore understood that numerous modifications and variations can be devised.

What is claimed is:

1. A power semiconductor device comprising a plurality of power modules each including a semiconductor element, a package that covers the semiconductor element and has a rectangular shape in plan view, and a power terminal electrically connected to the semiconductor element, wherein
outer shapes of the packages of the plurality of power modules are the same,
the plurality of power modules include:
a first half-bridge module in which the semiconductor element is made of a first semiconductor that is one of Si and a wide bandgap semiconductor; and
at least one of a second half-bridge module in which the semiconductor element is made of a second semiconductor that is the other of the Si and the wide bandgap semiconductor and which is connected in parallel with the first half-bridge module, a second relay module made of the second semiconductor and electrically connected with the first half-bridge module, and a second diode module made of the second semiconductor and electrically connected with the first half-bridge module,
in each of the first half-bridge module and the second half-bridge module, the semiconductor element includes two semiconductor switching elements connected in series, and the power terminals are provided on both short sides of the package,
in the second relay module, the semiconductor element includes two semiconductor switching elements connected in anti-series, and the power terminal is provided on one or both short sides of the package, and
in the second diode module, the semiconductor element includes two diodes connected in series, and the power terminals are provided on both short sides of the package.

2. The power semiconductor device according to claim 1, wherein
the plurality of power modules include the second half-bridge module.

3. The power semiconductor device according to claim 1, wherein
the plurality of power modules include the second relay module.

4. The power semiconductor device according to claim 3, wherein
the second relay module is electrically connected between a P bus or an N bus of the first half-bridge module and a power supply.

5. The power semiconductor device according to claim 3, wherein
the second relay module is electrically connected between an output terminal of the first half-bridge module and an intermediate potential of a power supply.

6. The power semiconductor device according to claim 3, wherein
the plurality of power modules further include a third relay module made of the first semiconductor and connected in parallel with the second relay module, and
in the third relay module, the semiconductor element includes two semiconductor switching elements connected in anti-series, and the power terminal is provided on one or both short sides of the package.

7. The power semiconductor device according to claim 1, wherein
the plurality of power modules include the second diode module.

8. The power semiconductor device according to claim 7, wherein
the second diode module is electrically connected between a connection point between the two semiconductor switching elements included in the first half-bridge module and an intermediate potential of a power supply, thereby implementing an NPC-type 3-level inverter.

9. The power semiconductor device according to claim 7, wherein
the plurality of power modules further include a third diode module made of the first semiconductor and connected in parallel with the second diode module, and
in the third diode module, the semiconductor element includes two diodes connected in series, and the power terminals are provided on both short sides of the package.

10. The power semiconductor device according to claim 1, wherein
a notch is selectively provided in a path portion of a main current in the plurality of power modules.
